(19) United States
(12) Patent Application Publication
(10) Pub. No.: US 2009/0211621 A1
(43) Pub. Date: Aug. 27, 2009

(54) Flexible Magnetically Attached Solar Electric Collector

(76) Inventor: Kenneth LeBlanc, Lake Placid, FL (US)

Correspondence Address: DONALD W. MEEKER, 924 EAST OCEAN FRONT, # E, NEWPORT BEACH, CA, 92661, US

(21) Appl. No.: 12/034,662

(22) Filed: Feb. 21, 2008

(51) Int. Cl. H01L 31/042; H01L 31/0256

(52) U.S. Cl. 136/244; 136/263

(57) ABSTRACT

A removable magnetically attached solar collector sheet system comprises a thin film, organic and printable photovoltaic sheet attached to a flexible magnetic sheet. The system removably attaches to any metal surface magnetically, conforms to that surface, and connects into the power supply of that object, such as homes, vehicles, commercial buildings, light poles, and other industrial applications.

### CROSS-REFERENCE TO RELATED APPLICATIONS

Not Applicable.

### STATEMENT REGARDING FEDERALLY SPONSORED RESEARCH OR DEVELOPMENT

Not Applicable.

### THE NAMES OF THE PARTIES TO A JOINT RESEARCH OR DEVELOPMENT

Not Applicable.

### BACKGROUND OF THE INVENTION

1. Field of the Invention

The present invention relates to flexible solar cells and particularly to a magnetically attachable portable solar collector sheet comprising a magnetic backing sheet and a thin film, organic and printable photovoltaic sheet with light sensitive electricity generating substance imprinted thereon which is adhered to the magnetic backing sheet.

2. Description of Related Art including information disclosed under 37 CFR 1.97 and 1.98

Solar energy is unlimited and easily captured with photovoltaic cells or materials which transform light into electricity, including artificial light sources as well as the sun. With rising prices of fuels, electricity becomes more expensive to produce (and most electricity production from fuels produces bad or hazardous environmental side effects), so it becomes increasingly desirable and necessary to use solar energy to produce electricity.

Prior solar electric collectors are usually permanent installations which are difficult and expensive to install and often unattractive on a roof.

Two U.S. Pat. No. 6,675,580 issued Jan. 13, 2004 and U.S. Pat. No. 6,295,818 issued Oct. 2, 2001 to Ansley, disclose a flexible solar power assembly which includes a flexible photovoltaic device attached to a flexible thermal solar collector. The solar power assembly can be rolled up for transport and then unrolled for installation on a surface, such as the roof or side wall of a building or other structure, by use of adhesive and/or other types of fasteners.

U.S. Pat. No. 5,409,549, issued Apr. 25, 1995 to Mori, claims a flexible solar cell module panel which is mounted on a roof of a building and united with roof rafters at low cost, whose installation and maintenance can be easily done, and which has long term reliability, especially with respect to protection of the solar cell modules. The solar cell modules of the solar cell module panel are mounted and fixed on the roof rafters, wherein at least one side edge portion of each solar cell module is held and fixed between the roof rafter and a solar cell module fastener member fixed to the roof rafter. Magnets may be used for assisting fixation of said solar cell modules to said roof structure.

U.S. Patent Application #20060225781, published Oct. 12, 2006 by Locher, puts forth a portable solar tarp or a field portable battery charger employing a solar tarp, utilizing flexible solar panels, solar fabric, or solar film. Around the perimeter of the solar tarp is a series of attachment points for straps. The attachment points can be grommets, loops, buckles, hooks, buttons, or grab loops and lines, and to which connected various straps (webbing, line, cord, or cable). The invention further discloses a versatile, adjustable strapping system utilizing straps, buckles, and hooks. The invention strapping system can attach almost any object to nearly any other object, such as back packs, luggage, vehicles, boats, permanent and portable shelters and buildings, mechanical equipment, and natural objects such as trees, rocks. The solar panel according to the invention can have the photovoltaic cells wired individually, or in a single line, because when parts of the photovoltaic system is subjected to shade, or if due to space constraint, parts of the photovoltaic system is covered or folded away, the remaining photovoltaic cells with useable energy are still able to function at peak capacity, since the covered cells will not become an energy drain upon the remaining cells. Further, the photovoltaic system is able to harness all available energy, regardless of the required or desired voltage and/or amperage for the system, thus converting any and all available energy into a useable current to either recharge batteries, or power a load.

U.S. Patent Application #20060028166, published Feb. 9, 2006 by Closset, concerns a photovoltaic device which is a portable solar charger comprising a flexible solar panel rollable on a cylindrical stiff core. The device comprises a flexible protection fully encircling the solar panel when in the rolled position. The device provides superior portability and ruggedness for indoor and outdoor applications.

U.S. Patent Application #20070017566, published Jan. 25, 2007 by Gaudiana, claims flexible photovoltaic modules, as well as related systems, methods, and components.

U.S. Pat. No. 7,176,543, issued Feb. 13, 2007 to Beernink, provides a method of eliminating curl for devices on thin flexible substrates, and devices made thereby. A thin film semiconductor device, such as a photovoltaic device, is fabricated on a lightweight substrate material which is affixed to a layer of material which is in turn supported by a carrier. In some instances the ferrous carrier allows for magnetic handling and guidance of the device during its fabrication and processing. Following the fabrication of the device, the carrier is removed such as by an etching process, leaving the layer of material adhered to the substrate. The adhered layer provides a balancing force to the back side of the substrate which minimizes or eliminates the tendency of the semiconductor device supported on the opposite side of the substrate to cause the substrate to curl. Also disclosed are devices and structures made by this method.

What is needed is a solar photovoltaic collector that is easy to install and easy to remove and portable which can fit onto a variety of surfaces and requires no mechanical connectors to attach it.

### BRIEF SUMMARY OF THE INVENTION

An object of the present invention is to provide a flexible magnetically attached solar photovoltaic collector sheet formed by a thin film, organic and printable photovoltaic sheet adhered to a flexible magnetic sheet that is easy to install and easy to remove and portable which can fit onto a variety of surfaces and requires no connectors to attach it.

Another object of the present invention is to also provide a permanent means of attaching with adhesive or mechanical means for applications which require such.

One more object of the present invention is to provide different colors and artistic designs on the exposed thin film, organic and printable photovoltaic sheet.

In brief, the present invention provides a magnetically attachable portable solar sheet comprising a magnetic backing sheet and a thin film, organic and printable photovoltaic sheet with light sensitive electricity generating substance imprinted thereon which is adhered to the magnetic backing sheet.

The purpose of the device is to provide a solar energy collection system that is easy to install and remove and provides portability.

An advantage of the present invention is that it provides easy installation by adhering magnetically to any metal surface.

Another advantage of the present invention is that it is easily removed from the application when no longer needed or in inclement weather situations.

One more advantage of the present invention is that is may come in different colors and artistic designs to match or enhance the object the panels are applied to.

An additional advantage of the present invention is that the system may be additionally attached using adhesive or mechanical means when the application calls for a permanent attachment.

### BRIEF DESCRIPTION OF THE SEVERAL VIEWS OF THE DRAWINGS

These and other details of my invention will be described in connection with the accompanying drawings, which are furnished only by way of illustration and not in limitation of the invention, and in which drawings:

FIG. 1 is a perspective view of a roll of the magnetically attached solar collector sheets of the present invention showing the bottom magnetic sheet and the thin film, organic and printable photovoltaic sheet adhered on top of the magnetic sheet;

FIG. 2 is a side elevational view of a metal truck having the magnetically attached solar collector sheets of FIG. 1 attached to the sides and roof of the truck;

FIG. 3 is a side elevational view of a metal car having the magnetically attached solar collector sheets of FIG. 1 attached to the sides, trunk, and roof of the car;

FIG. 4 is a perspective view of a sloped metal roof having the magnetically attached solar collector sheets of FIG. 1 attached to the roof and one being rolled onto the roof to attach the sheet;

FIG. 5 is a perspective view of a long handled rolling tube with an elongated adjustable handle and a pivotally attached roller orthogonally attached the end of the handle for rolling out the magnetically attached sheets to apply them to metal surfaces, such as the sloped metal roof of FIG. 4;

FIG. 6 is a side elevational view of a metal street light pole having the magnetically attached solar collector sheets of FIG. 1 attached around the pole;

FIG. 7 is a front elevational view of a building with metal siding and roofing having the magnetically attached solar collector sheets of FIG. 1 attached to the metal siding and metal roof of the building;

FIG. 8 is a side elevational view of a ship with a metal hull having the magnetically attached solar collector sheets of FIG. 1 attached to the metal hull of the ship;

FIG. 9 is a perspective view of a highway showing a truck traveling on the highway having the magnetically attached solar collector sheets of FIG. 1 attached to the roof of the truck and a back of a highway sign having the magnetically attached solar collector sheets of FIG. 1 attached to the back of the highway sign.

### DETAILED DESCRIPTION OF THE INVENTION

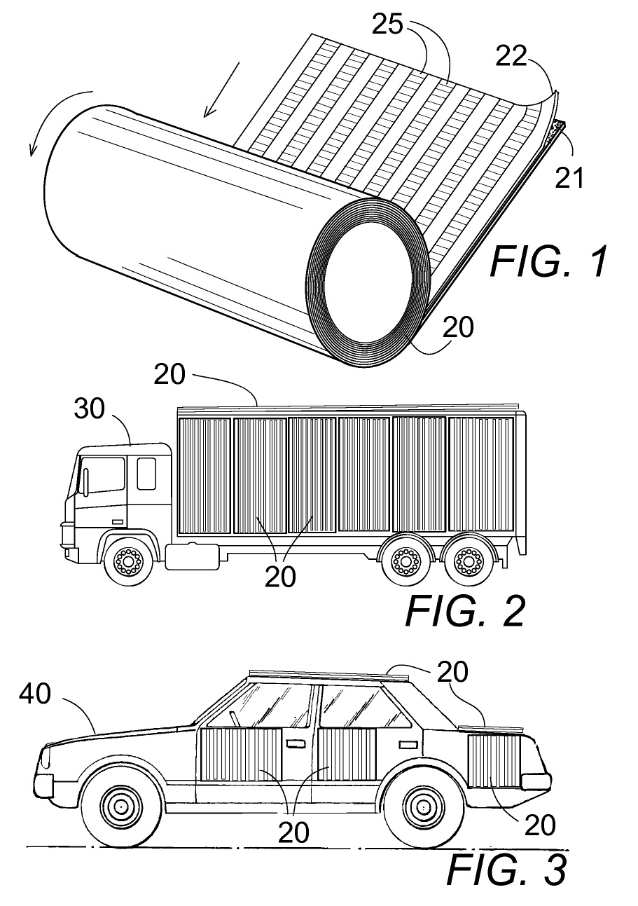

In FIGS. 1-9, a magnetically attached solar collector sheet 20 comprises a flexible magnetic sheet 21 for attaching to and conforming to the shape of an external metal surface and an outer thin film, organic and printable photovoltaic sheet 22 adhered to the magnetic sheet, the thin film, organic and printable photovoltaic sheet 22 having a light sensitive electricity generating substance 25 imprinted thereon in a desired pattern and color for collecting electricity.

In FIG. 1, the magnetically attached solar collector sheet 20 which is rolled into a roll for storage and shipping and rolled out onto a metal surface to attach the magnetically attached solar collector sheet 20 to a metal surface by magnetic attraction, the magnetically attached solar collector sheet conforming to the shape of the metal surface. The magnetically attached solar collector sheet is rolled up with the magnetic sheet 21 exposed on the outside of the roll. The magnetically attached solar collector sheet may then be unrolled onto a metal surface, as shown in FIG. 4, with the magnetic sheet 21 side contacting the metal surface and the thin film, organic and printable photovoltaic sheet 22 exposed to sunlight for use as an instantly installed removable solar collector for collecting electricity from the sun. The thin film, organic and printable photovoltaic sheet 22 is imprinted with light sensitive electricity generating substance 25 imprinted on thin plastic sheet in colored lines in this case, but could be any configuration or color that can be printed.

In FIG. 4, an electrical pick up strip 26 magnetically attached to the metal surface at an end of each magnetically attached solar collector sheet 20 contacts each of the imprinted strips of electricity generating material 25 to transfer the electricity to a continuous electricity transmitting strip 24 which may be magnetically attached to a metal fascia 54 or other part of the structure via electrical connectors 28. The electrical pick up strip 26A (shown dashed) could alternately be positioned along a peak of the roof. An electricity transmitting strip could alternately be connected directly to the magnetically attached solar collector sheets 20 in various applications. The electricity transmitting strip 24 connects to an electrical system for immediate use in the system, or for storage in a battery, or directed through a transformer to adapt the electricity for compatibility with electrical system. As the magnetically attached solar collector sheet 20 is exposed to sunlight, the electricity is generated and transferred to the electrical system.

In FIGS. 1-9, the thin film, organic and printable photovoltaic sheet 22 preferably comprises a transparent plastic sheet and the electricity generating substance 25 is imprinted on a side of the plastic sheet adhered to the magnetic sheet so that the electricity generating substance 25 is shielded by the plastic sheet from exposure to weather conditions, while the solar energy is collected by the sun shining through the transparent plastic sheet onto the electricity generating substance.

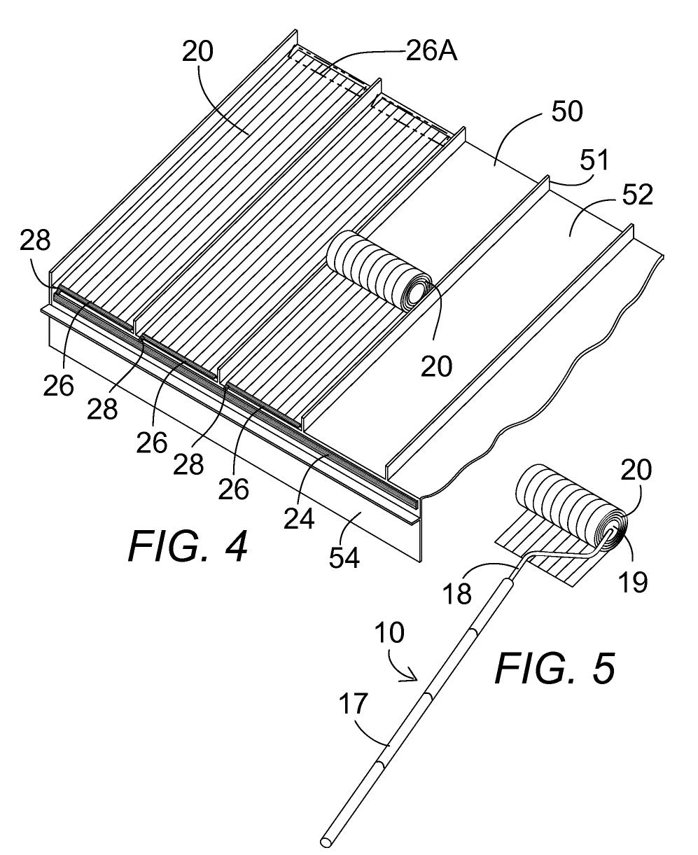

FIGS. 1-9 show many different possible applications and the present invention may integrate colors and possibly designs on the thin film, organic and printable photovoltaic sheets. For example, on a car 40 (FIG. 3), a color can be selected that matches the color on the hybrid car to which the sheets are being applied, such as silver, black, wood grain side panels, etc. They are removable and transferable from one vehicle to another and also work on trucks 30 (FIG. 2), RV's, etc. There may be additional fastening methods especially on a forward edge to ensure that they stay on during high speeds.

FIG. 5 shows a roll applying tool 10 comprising an elongated handle 17, which may be telescoping to extend the length, and a roll insert arm 18 with a roller 19 pivotally attached at a distal end of the handle so that the roller 19 is inserted in the rolled up magnetically attached solar collector sheet 20 to attach the magnetically attached solar collector sheet 20 by moving the roll over the metal surface to unroll the magnetically attached solar collector sheet 20 thereby attaching it to the metal surface of the roof 50.

In use, a user can just roll out the magnetically attached solar collector sheets 20 on any metal surface and the magnetic attraction makes it stay in place instantly, and then hook up the electrical connectors to the membranes to supply electricity to any electrical device or battery. The present invention can be applied to metal roofs 50 (FIG. 4), metal sides of buildings 60 (FIG. 7) or metal doors or awnings, or to vehicles (FIGS. 2 and 3) or any metal surface for an instant electricity generator from any light source including direct sunlight, indirect outdoor light or artificial lights.

The magnetically attached solar collector sheets 20 can be directly applied to anything metallic as a temporary (easily removable) installation or permanent installation. Adhesive or mechanical (screws, fasteners, brackets) may be utilized as a means to further attach said product to various installations to make them a more permanent installation if needed.

As shown in FIGS. 4 and 5, when attaching to a roof 50 on the flat metal panels 52 of the roof between the protruding ridges 51, it is possible using the roll applying tool 10 to unroll the rolls from the eave up and tie in the power connections at the eave. Using this technique, the whole installation could be done from the ground without having to go on the roof. The roller 10 would unroll the magnetically attached solar collector sheet 20 from the bottom up. And then it could be used to roll it back up from the bottom up again. The wire connections can also be on skinny magnetic strips that run along the drip to connect all the panels. A homeowner can take this system with them when they move from one house to another, as it can be a portable and temporary system or a permanently attached system which may have supplemental attaching means, such as adhesives or mechanical connectors as needed.

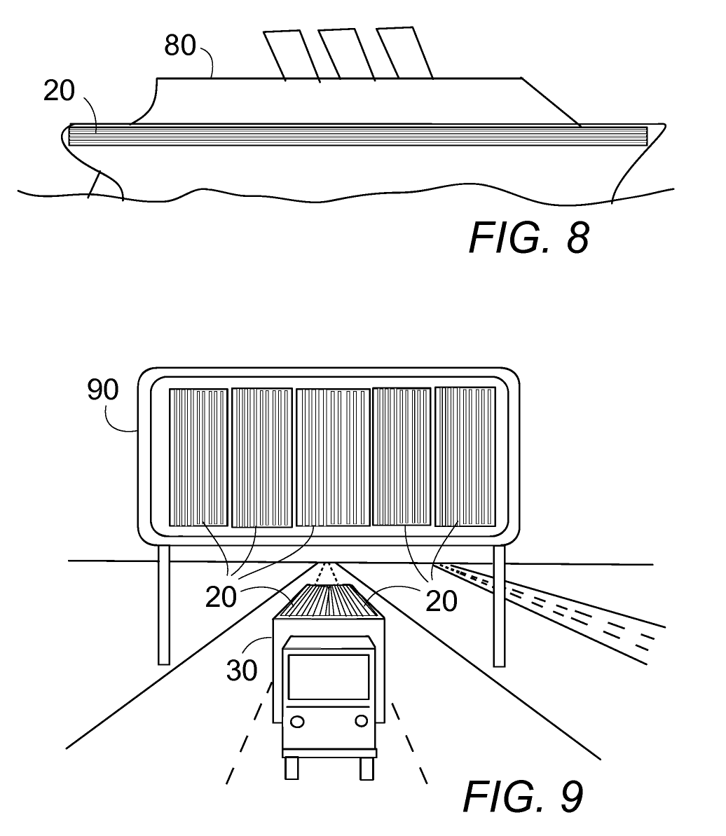

In FIG. 8, the magnetically attached solar collector sheets 20 are attached to the metal hull of the ship 80 for providing electricity to the ship.

In FIG. 9, the magnetically attached solar collector sheets 20 are attached to the metal roof of a truck 30 and to a back of a metal highway sign 90.

The present invention can be applied to any metal surface enabling many different applications including, but not limited to the following applications:

### Metal Roofing Application

1) Installation on metal roofs of houses or commercial buildings can be accomplished by unrolling the magnetic material from the bottom of the eave upward utilizing an unrolling arm similar to a paint roller device on an extending arm, as in FIGS. 4 and 5.
2) Removal of the panels can be accomplished by rolling (the panel) up the roof then once in a complete roll rolling the roll back down as a complete roll.
3) The connection of power to the magnetically attached solar collector sheet 20 is accomplished by connecting the wires of the separate panels to a continuous power strip that is also magnetic and or adhesive backed which is run along the drip edge material of the roofing system. This power strip connects all the panels to the system of the house.
4) This system is meant to be able to be installed by a homeowner in most instances. It is also intended to be able to be removed and relocated to a new house by the homeowner if desired. It is also intended that this system can be removed and stored by the homeowner if circumstances such as a hurricane were approaching. It can then be saved from damage and reinstalled after the hurricane to produce power once again. The system can be moved to a new location when a resident moves.
5) This system is also intended to be installed on Mobile Homes, Manufactured Homes, Sheds, Gazebos, Metal in garage or porch structures, etc.

### Commercial Building/Industrial Building Applications

1) Some commercial buildings utilize metal wall panels. As shown in FIG. 7, the present invention would be used in these applications. Once attached magnetically to the wall, adhesive and or mechanical fastening devices may be used to further make the attachment more permanent. The attachment methods would be based on each situation and would utilize existing means and methods.
2) Magnetically backed and or adhesive backed power (wiring) strips would be utilized to connect these solar panels together and then to the building's power system.
3) The system of the present invention also has the capability to be installed on water towers, bridge spans, industrial tanks, industrial buildings, etc.—any structure that is metallic.

### Light Poles

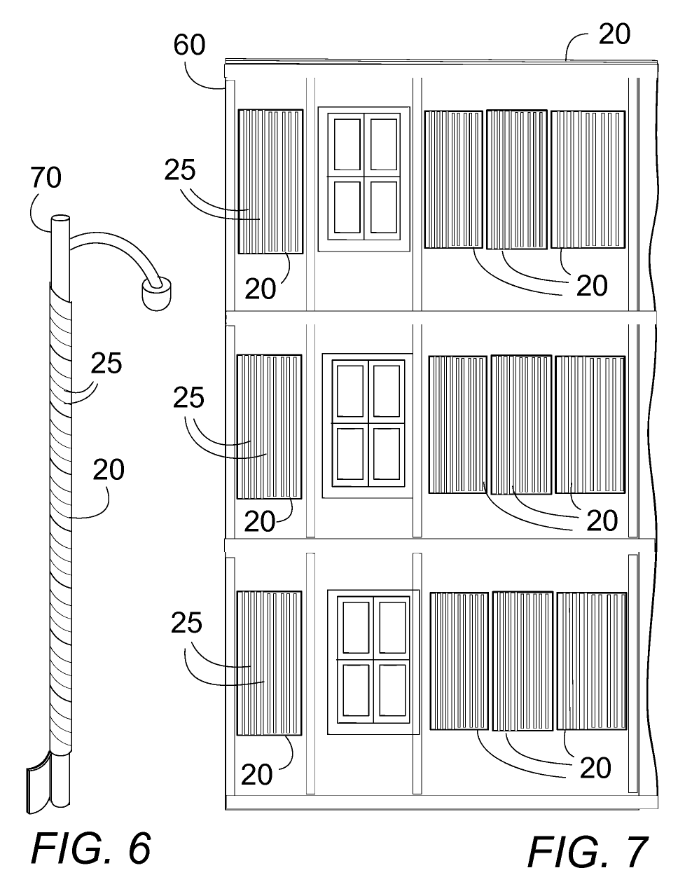

1) In FIG. 6, the system of the present invention can be magnetically attached to any light pole 70 that is metallic and can be wrapped with the sheet. The invention can also be adhesively or mechanically fastened to the pole to make it a permanent installation using adhesive and or mechanical means such as clamps, screws, etc.
2) This installation would be wired inside the pole to connect it to the power grid of the lighting system or allow the light to be wired to a battery system and keep it off the power grid and independent of the power grid.

### Garage Doors

1) The magnetically attached solar collector sheets 20 could be installed directly to metallic garage door panels. Flexible wires would connect each panel system to each other and to the power grid of the house. These panels may be ordered in colors and or patterns to match the garage door colors or house colors.
   Cars, Trucks, RV9s, Trailers, Metal Containers, Box trucks
1) FIGS. 2 and 3 show the magnetically attached solar collecting sheets 20 can also be installed on vehicles. An example would be to install in on the roof of a Hybrid car and wire it to the battery pack to increase the mileage of the vehicle. The solar panels can be ordered to match the factory color of the car, wood grain side panels, or use other artistic designs. They also can be embedded into standard signage that would serve as advertising on a vehicle.
2) The solar panel will be connected to the power grid of the car utilizing magnetically and/or adhesively backed wires.
3) The solar panel can also power rechargeable devices such as phones, Ipods, gps, ctc. Another use would be to recharge a car battery.
4) The present system may be utilized on trucks, RV's, trailers, metal container boxes, box trucks, etc.
5) To adhere magnetically attached solar collector sheets to vehicles, one may use spray adhesive under the magnetic sheet to help adhere the solar panels down during high winds or very fast driving, possibly on the leading edge of the panel to help resist against the wind or on a metal roof. On cars, the present invention may be installed just like a sign is installed. The wiring will either be on skinny magnetic strips likely with adhesive under or wire integrated with a skinny strip of tape that the protective strip peels off the back to apply.

The present invention is adapted for installation on a whole range of places, such as garage doors, light poles 70 in FIG. 6, commercial buildings 60 with metal panels in FIG. 7, bridges, etc. It may incorporate other ways to permanently mount in some cases such as adhesive tape or spray glue to supplement the magnetic attachment. As in some cases installations can be removed in case of a hurricane, but in others such as light poles, bridges, commercial buildings, etc. they cannot possibly be removed due to severe wind conditions, so a strong magnetic material may be opted for and then the seams fastened in the field with glue, tape or mechanical (screw) fasteners.

Depending on the application, the system may further comprise at least one supplemental fastening means taken from the list of fastening means comprising spray adhesive, snap ties, screws, plates, brackets, adhesive tape, glues, bolts or other means for securing part or all of the sheets.

It is understood that the preceding description is given merely by way of illustration and not in limitation of the invention and that various modifications may be made thereto without departing from the spirit of the invention as claimed.

What is claimed is:

1. A magnetically attached solar collector system comprising:
a magnetically attached solar collector sheet comprising planar flexible rubberized magnetically attractive material which is rolled into a roll for storage and shipping and rolled out onto a metal surface to attach the magnetic sheet to the metal surface by magnetic attraction, the magnetic sheet conforming to the shape of the metal surface;
a thin film, organic and printable photovoltaic sheet comprising a thin flexible plastic sheet imprinted with a with light sensitive electricity generating substance on at least one surface of the plastic sheet, the thin film, organic and printable photovoltaic sheet adhered over the magnetic sheet to form a magnetically attached solar collector sheet, so that the magnetically attached solar collector sheet is rolled up with the magnetic sheet exposed on the outside of the roll and the magnetically attached solar collector sheet is unrolled onto a metal surface with the magnetic side contacting the metal surface and the thin film, organic and printable photovoltaic sheet exposed to sunlight for use as an instantly installed removable solar collector for collecting electricity from the sun;
an electrical system attached to the imprinted electricity generating substance to draw electricity therefrom as the magnetically attached solar sheet is exposed to sunlight for use and storage of the electricity in the electrical system.

2. The system of claim 1 wherein the thin film, organic and printable photovoltaic sheet comprises a transparent plastic sheet and the electricity generating substance is imprinted on a side of the plastic sheet adhered to the magnetic sheet so that the electricity generating substance is shielded by the plastic sheet from exposure to weather conditions while the solar energy is collected by the sun shining through the transparent plastic sheet onto the electricity generating substance.

3. The system of claim 1 wherein a portion of the electrical system connecting to the electricity generating substance is attached to magnetic material which is removably attached to the metal surface by magnetic attraction.

4. The system of claim 1 further comprising a roll applying tool comprising an elongated handle and a roll insert arm pivotally attached at a distal end of the handle so that the roll insert arm is inserted in the rolled up magnetically attached solar collector sheet to attach the magnetically attached solar collector sheet by moving the roll over the metal surface to unroll the magnetically attached solar collector sheet thereby attaching it to the metal surface.

5. The system of claim 1 further comprising at least one supplemental fastening means taken from the list of fastening means comprising spray adhesive, snap ties, screws, plates, brackets, adhesive tape, glues, bolts.
